(19) United States
(12) Patent Application Publication
(10) Pub. No.: US 2025/0323199 A1
(43) Pub. Date: Oct. 16, 2025

(54) BOND PAD FOR REDUCED CONTACT RESISTANCE

(71) Applicant: Taiwan Semiconductor Manufacturing Company, Ltd., Hsinchu (TW)

(72) Inventors: Ching Ju Yang, Hsinchu (TW); Yao-Wen Chang, Taipei (TW)

(21) Appl. No.: 19/250,206

(22) Filed: Jun. 26, 2025

Related U.S. Application Data
(63) Continuation of application No. 18/584,062, filed on Feb. 22, 2024.
(60) Provisional application No. 63/581,331, filed on Sep. 8, 2023.

(51) Int. Cl. H01L 23/00; H01L 23/498; H01L 25/00; H01L 25/065

(52) U.S. Cl. CPC H01L 24/09; H01L 23/49838; H01L 24/05; H01L 24/16; H01L 24/94; H01L 25/0657; H01L 25/50; H01L 2224/05147; H01L 2224/0903; H01L 2224/16148; H01L 2224/94; H01L 2225/06513; H01L 2924/12041

(57) ABSTRACT

Various embodiments of the present disclosure are directed towards an integrated chip having an interconnect structure overlying a substrate. The interconnect structure includes a conductive wire disposed in a dielectric structure. The conductive wire comprises a body structure. A passivation structure overlies the interconnect structure. A bond pad overlies the passivation structure. The bond pad comprises an upper pad structure on the passivation structure and a plurality of lower bond structures extending through the passivation structure to the conductive wire. The lower bond structures respectively comprise a vertical bond structure and a diffusion barrier layer disposed along a lower surface and opposing sidewalls of the vertical bond structure. The upper pad structure comprises a first conductive layer vertically stacked with a second conductive layer

### REFERENCE TO RELATED APPLICATIONS

This Application is a Continuation of U.S. application Ser. No. 18/584,062, filed on Feb. 22, 2024, which claims the benefit of U.S. Provisional Application No. 63/581,331, filed on Sep. 8, 2023. The contents of the above-referenced patent applications are hereby incorporated by reference in their entirety.

### BACKGROUND

The semiconductor industry has continually improved the processing capabilities and power consumption of integrated chips by shrinking the minimum feature size. However, in recent years, process limitations have made it difficult to continue shrinking the minimum feature size. The stacking of two-dimensional (2D) integrated chips into three-dimensional (3D) integrated chips has emerged as a potential approach to continue improving processing capabilities and power consumption of integrated chips. Bond pads are used to electrically couple stacked 2D integrated chips together.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip comprising a bond pad having an upper pad structure and a plurality of lower bond structures configured to decrease a contact resistance and increase a reliability of the integrated chip.

FIGS. 2A-2D illustrate cross-sectional views of some other embodiments of the integrated chip of FIG. 1.

FIG. 2E illustrates a top view of some embodiments of the integrated chip of FIG. 2D.

FIGS. 3A and 3B illustrate cross-sectional views of some embodiments of an integrated chip comprising a plurality of bond pads disposed over an interconnect structure.

FIGS. 4A and 4B illustrate cross-sectional views of some embodiments of a stacked integrated chip structure having an upper semiconductor die bonded to bond pads of a semiconductor die.

FIGS. 5-16 illustrate cross-sectional views of some embodiments of a method of forming an integrated chip comprising a bond pad having an upper pad structure and a plurality of lower bond structures configured to decrease a contact resistance and increase a reliability of the integrated chip.

FIGS. 17-20 illustrate cross-sectional views of some embodiments of a method of forming a stacked integrated chip structure having an upper semiconductor die bonded to bond pads of a semiconductor die.

FIG. 21 illustrates a flowchart of some embodiments of a method of forming a stacked integrated chip structure having an upper semiconductor die bonded to bond pads of a semiconductor die.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Typically, semiconductor dies include an interconnect structure overlying a substrate. A passivation structure overlies the interconnect structure and a plurality of bond pads are disposed within the passivation structure and coupled to wires in the interconnect structure. One or more semiconductor devices (e.g., transistor(s), varactor(s), resistor(s), capacitor(s), etc.) are arranged in, on, or over the substrate and are electrically coupled to the bond pads by way of the interconnect structure. The bond pads are configured to facilitate electrical coupling to a printed circuit board (PCB), a micro-light emitting diode (LED) die, another semiconductor die by, for example, a metallic bonding process.

Each bond pad may comprise an upper pad structure and one or more lower bond structures. The upper pad structure is disposed along an upper surface of the passivation structure. The one or more lower bond structures extend through the passivation structure from the upper pad structure to a corresponding wire in the interconnect structure. The bond pads may have a number of different configurations. For example, the upper pad structure and the one or more lower bond structures of the bond pad are a single continuous structure comprising a first material (e.g., aluminum). However, in such a configuration the upper pad structure is too thick for applications that call for a low profile (e.g., too thick for micro-LED applications). Further, the first material (e.g., aluminum) is prone to delamination and/or stress when exposed to an etchant (e.g., vapor hydrogen fluoride) utilized to prepare the bond pad for the metallic bonding process. For instance, the etchant may be used to remove a dielectric over and/or around the bond pad before the metallic bonding process. In another example, the one or more lower bond structures of the bond pad may comprise a second material (e.g., tungsten) that may be different from a material(s) of the upper pad structure. However, in such an embodiment, the second material (e.g., tungsten) has a relatively high resistance (e.g., greater than that of the wires) that increases a contact resistance between the one or more semiconductor devices and the PCB, the micro-LED die, or the another semiconductor die. As a result, a performance and reliability of the semiconductor die is reduced.

Various embodiments of the present application are directed towards an integrated chip comprising a bond pad configured to reduce a contact resistance and a height of the integrated chip. The integrated chip comprises one or more semiconductor devices disposed on and/or within a substrate. An interconnect structure overlies the substrate and is electrically coupled to the one or more semiconductor devices. A passivation structure overlies the interconnect structure. The bond pad is disposed in the passivation structure and is electrically coupled to the interconnect structure. The bond pad comprises an upper pad structure over the passivation structure and lower bond structures extending from the upper pad structure to a wire in the interconnect structure. The lower bond structures respectively comprise a vertical bond structure and a diffusion barrier layer disposed along opposing sidewalls and a lower surface of the vertical bond structure. The vertical bond structure comprises a first conductive material (e.g., copper) having a relatively low resistance (e.g., lower than that of tungsten). The vertical bond structure having the relatively low resistance decreases a contact resistance between the bond pad and another semiconductor structure (e.g., a micro-LED die, another semiconductor die, etc.) bonded to the bond pad. This increases a performance and reliability of the integrated chip.

Further, the upper pad structure comprises a plurality of conductive layers having one or more second conductive materials (e.g., titanium, tantalum nitride) different from the first conductive material. The upper pad structure having the conductive layers facilitates reducing a height of the bond pad. In addition, the one or more second conductive materials of the conductive layers is/are not prone delamination and/or stress when exposed to an etchant (e.g., vapor hydrogen fluoride) utilized to prepare the bond pad for a bonding process. As a result, the bond pad facilitates decreasing an overall height of the integrated chip for applications that call for a low profile (e.g., in a micro-LED application) and further increasing a stability and reliability of the integrated chip.

FIG. 1 illustrates a cross-sectional view of some embodiments of an integrated chip 100 comprising a bond pad 120 having an upper pad structure 124 and a plurality of lower bond structures 122 configured to decrease a contact resistance and increase a reliability of the integrated chip 100.

The integrated chip 100 includes a semiconductor device 104 disposed within and/or on a semiconductor substrate 102 (e.g., a silicon substrate). An interconnect structure 106 is disposed on a front-side surface 102f of the semiconductor substrate 102. The semiconductor device 104 may, for example, be or comprise a transistor, a varactor, a resistor, a capacitor, a doped active region of the semiconductor substrate 102, or some other suitable semiconductor device.

The interconnect structure 106 comprises a plurality of conductive interconnect layers arranged within an interconnect dielectric structure 108. The plurality of conductive interconnect layers includes a plurality of conductive contacts 110, a plurality of conductive wires 112, and a plurality of conductive vias 113 vertically stacked with one another. The conductive wires 112 are configured to provide a lateral connection (i.e., a connection parallel to an upper surface of the semiconductor substrate 102), whereas the conductive vias 113 and the conductive contacts 110 are configured to provide for a vertical connection between the conductive wires 112. The interconnect structure 106 comprises a topmost conductive wire 112t having a top surface aligned with a top surface of the interconnect dielectric structure 108. The semiconductor device 104 is electrically coupled to the interconnect layers of the interconnect structure 106.

A passivation structure 114 is disposed along an upper surface of the interconnect structure 106. The passivation structure 114 comprises a first passivation layer 116 vertically stacked with a second passivation layer 118. The bond pad 120 overlies the interconnect structure 106. The bond pad 120 comprises the upper pad structure 124 disposed on a top surface of the passivation structure 114 and the plurality of lower bond structures 122 continuously extending from the upper pad structure 124 to a conductive structure in the interconnect structure 106. In some embodiments, the plurality of lower bond structures 122 directly contact and are electrically coupled to the topmost conductive wire 112t. The bond pad 120 is configured to electrically couple the semiconductor device 104 to another semiconductor die (not shown). A protection layer 134 is disposed along the top surface of the passivation structure 114 and along opposing sidewalls of the upper pad structure 124.

The passivation structure 114 comprises pairs of opposing sidewalls defining trenches extending through a height of the passivation structure 114. The lower bond structures 122 are disposed within a corresponding trench in the passivation structure 114. Further, the lower bond structures 122 respectively comprise a vertical bond structure 128 and a diffusion barrier layer 126. The diffusion barrier layer 126 is disposed around a lower surface and opposing sidewalls of the vertical bond structure 128. In various embodiments, the vertical bond structure 128 comprises a first conductive material (e.g., copper) having a relatively low resistivity. In some embodiments, the resistivity of the first conductive material is less than that of tungsten (e.g., less than 5.6*10⁻⁸ ohm-meter (Ω·m)). The lower bond structures 122 comprising the vertical bond structure 128 with the relatively low resistivity decreases a contact resistance between the bond pad 120 and the another semiconductor die (not shown). This increases a performance and reliability of the integrated chip 100. Further, the diffusion barrier layer 126 is configured to mitigate diffusion of the first conductive material (e.g., copper) from the vertical bond structure 128 to adjacent structures of the integrated chip 100. As a result, a stability and reliance of the integrated chip 100 are increased.

In some embodiments, the upper pad structure 124 comprises a first conductive layer 130 vertically stacked with a second conductive layer 132. The first conductive layer 130 comprises a second conductive material (e.g., titanium nitride, tantalum nitride) configured to mitigate diffusion of the first conductive material (e.g., copper) from the lower bond structures 122. In various embodiments, a bottom surface of the first conductive layer 130 directly contacts a top surface of the vertical bond structure 128 and a top surface of the diffusion barrier layer 126. In some embodiments, the first conductive layer 130 may be configured as and/or referred to as an upper diffusion barrier layer. Further, the second conductive layer 132 comprises a third conductive material (e.g., titanium, platinum) different from the first and second conductive materials. The second conductive layer 132 is configured to mitigate damage to underlying layers and/or structures of the bond pad 120 from an etchant (e.g., vapor hydrogen fluoride) utilized to prepare the integrated chip 100 for a bonding process. This, in part, mitigates delamination and/or stress on the layers of the bond pad 120. In addition, the upper pad structure 124 having the first and second conductive layers 130, 132 facilitates accurately controlling and/or shrinking a height of the bond pad 120. Accordingly, by virtue of the bond pad 120 having the lower bond structures 122 with the relatively low resistivity and the upper pad structure 124 configured to reduce diffusion of the first material (e.g., copper) and mitigating damage from the etchant during the fabrication process, the contact resistance of the integrated chip 100 is reduced and a performance and reliability of the integrated chip is increased.

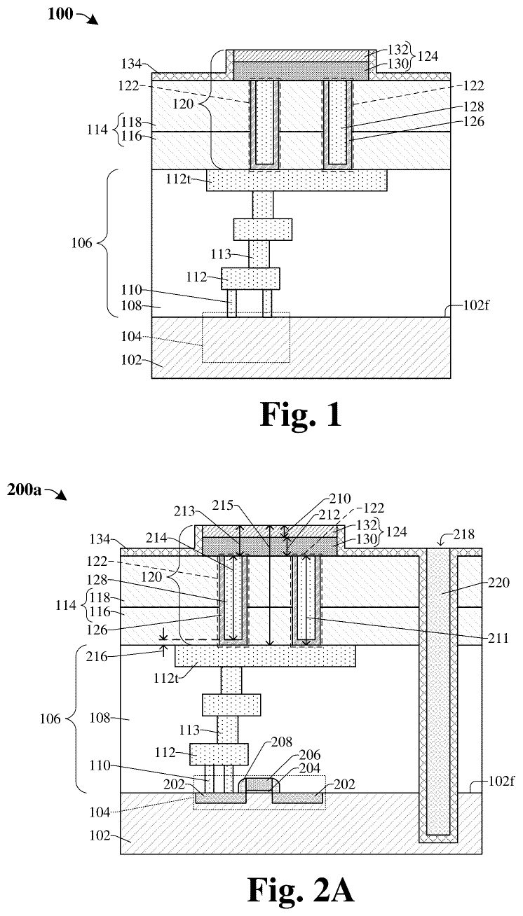

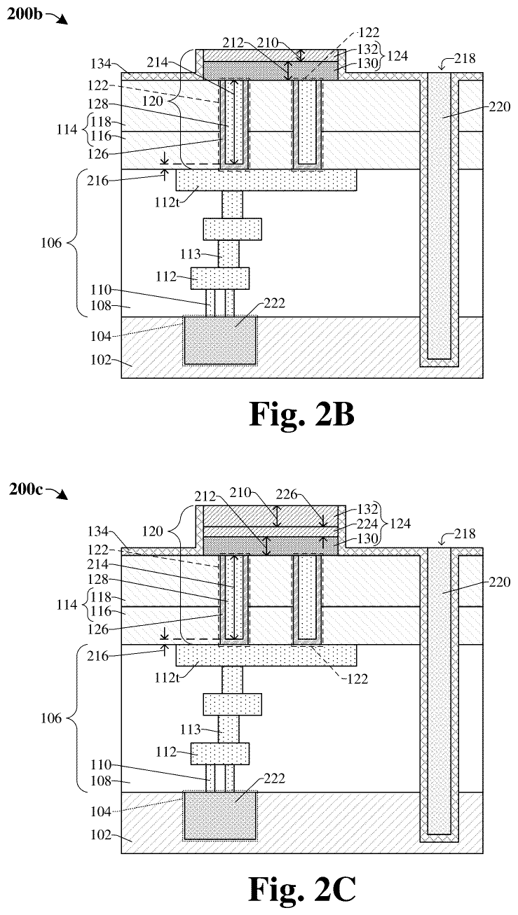

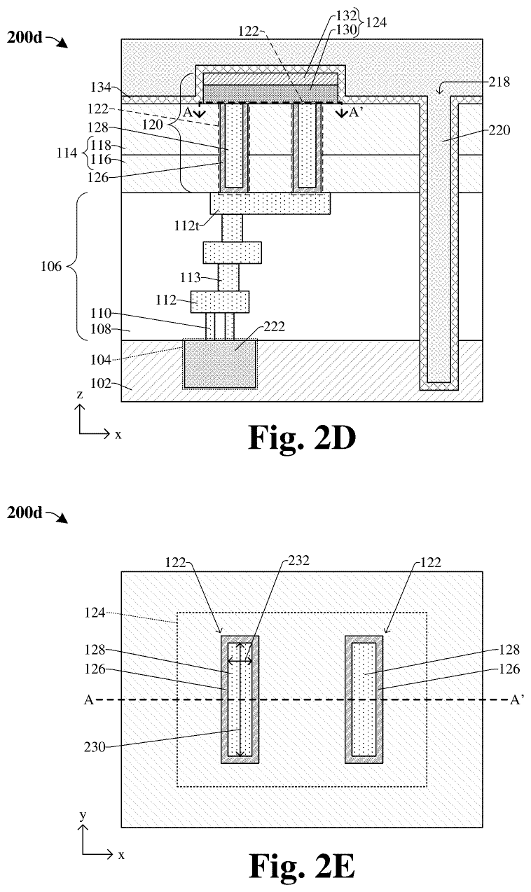

FIG. 2A illustrates a cross-sectional view of some embodiments of an integrated chip 200a corresponding to some other embodiments of the integrated chip 100 of FIG. 1.

The integrated chip 200a comprises an interconnect structure 106 overlying a semiconductor substrate 102. The semiconductor substrate 102 may, for example, be a bulk substrate (e.g., a bulk silicon substrate), silicon, germanium, silicon germanium, one or more epitaxial silicon layers, a silicon-on-insulator (SOI) substrate, or some other suitable substrate. A semiconductor device 104 is disposed within and/or on the semiconductor substrate 102. In some embodiments, the semiconductor device 104 may be configured as a transistor. In such embodiments, the semiconductor device 104 comprises source/drain regions 202 disposed in the semiconductor substrate 102, a gate electrode 206 over the semiconductor substrate 102 between the source/drain regions 202, a gate dielectric layer 204 under the gate electrode 206, and a sidewall spacer structure 208 disposed along sidewalls of the gate electrode 206 and the gate dielectric layer 204. Source/drain region(s) may refer to a source or a drain, individually or collectively depending upon the context.

The interconnect structure 106 is disposed along a front-side surface 102f of the semiconductor substrate 102. The interconnect structure 106 comprises the plurality of conductive contacts 110, the plurality of conductive wires 112, and the plurality of conductive vias 113 disposed within the interconnect dielectric structure 108. The plurality of conductive wires 112 comprises a topmost conductive wire 112t. The plurality of conductive wires 112, the plurality of conductive vias 113, and the plurality of conductive contacts may, for example, be or comprise copper, aluminum, aluminum copper, tungsten, some other conductive material, or the like. The interconnect dielectric structure 108 comprises a plurality of dielectric layers vertically stacked with one another. The plurality of dielectric layers may, for example, be or comprise silicon dioxide, silicon glass, un-doped silicon glass, silicon nitride, silicon carbide, another dielectric material, or any combination of the foregoing.

The passivation structure 114 overlies the interconnect structure 106. The passivation structure 114 comprises a first passivation layer 116 disposed on the interconnect structure 106 and a second passivation layer 118 over the first passivation layer 116. The first passivation layer 116 may, for example, be or comprise silicon nitride, silicon carbide, another dielectric material, or any combination of the foregoing. In some embodiments, a thickness of the first passivation layer 116 is about 3,000 angstroms, within a range of about 2,500 to 3,500 angstroms, or some other suitable value. The second passivation layer 118 may, for example, be or comprise silicon dioxide, silicon glass, un-doped silicon glass, another dielectric material, or any combination of the foregoing. In various embodiments, a thickness of the second passivation layer 118 is about 5,500 angstroms, within a range of about 5,000 to 6,000 angstroms, or some other suitable value.

The bond pad 120 overlies the passivation structure 114 and contacts the topmost conductive wire 112t. The bond pad 120 is configured to electrically couple the semiconductor device 104 to another semiconductor die (not shown) by way of the interconnect structure 106. The bond pad 120 comprises an upper pad structure 124 disposed along the passivation structure 114 and a plurality of lower bond structures 122 extending from the upper pad structure 124 to the interconnect structure 106. The bond pad 120 and the semiconductor device 104 are disposed within a semiconductor die region of the semiconductor substrate 102. An isolation trench 218 is adjacent to the semiconductor die region and extends through the passivation structure 114, the interconnect structure 106, and at least a portion of the semiconductor substrate 102. In some embodiments, the isolation trench 218 is disposed along and/or defines a scribe line, where a singulation process may be performed along the isolation trench 218 to singulate the semiconductor die region. A protection layer 134 is disposed along sidewalls of the upper pad structure 124 and lines the isolation trench 218. In further embodiments, a dielectric layer 220 overlies the protection layer 134 and fills the isolation trench 218. The dielectric layer 220 may, for example, be or comprise an oxide such as silicon dioxide or some other suitable material. In yet further embodiments, the dielectric layer 220 may be omitted (not shown). The protection layer 134 may, for example, be or comprise a metal oxide such as aluminum oxide or some other dielectric material. A thickness of the protection layer 134 may, for example, be about 400 angstroms, within a range of about 350 to 450 angstroms, or some other suitable value.

The lower bond structures 122 respectively comprise a vertical bond structure 128 and a diffusion barrier layer 126. In some embodiments, the diffusion barrier layer 126 continuously laterally wraps around an outer perimeter of the vertical bond structure 128. In further embodiments, when viewed in cross-sectional, the diffusion barrier layer 126 is U-shaped and extends along opposing sidewalls and a bottom surface of the vertical bond structure 128. In yet further embodiments, a top surface of the vertical bond structure 128 is vertically aligned with a top surface of the diffusion barrier layer 126 and a top surface of the passivation structure 114. The vertical bond structure 128 comprises a first conductive material (e.g., copper) having a relatively low resistivity (e.g., less than about 5.6*10⁻⁸ Ω·m). The vertical bond structure 128 having the relatively low resistivity decreases the contact resistance between the bond pad 120 and the another semiconductor die (not shown), thereby increasing a performance of the integrated chip. In some embodiments, the vertical bond structure 128 consists of or consists essentially of copper. In various embodiments, the vertical bond structure 128 is a single structure comprising a single continuous material (e.g., copper). In some embodiments, the conductive wires 112 and the conductive vias 113 comprise the first conductive material (e.g., copper).

In some embodiments, the first conductive material (e.g., copper) of the vertical bond structure 128 may have a high likelihood to diffuse out to adjacent structures (e.g., the passivation structure 114). Diffusion of the first conductive material away from the lower bond structures 122 may result in leakage current, degradation of adjacent dielectric material, reduction of stability and reliability. In various embodiments, the diffusion barrier layer 126 comprises a second conductive material configured to mitigate diffusion of the first conductive material from the vertical bond structure 128. Thus, the diffusion barrier layer 126 comprising the second conductive material and being disposed around and under the vertical bond structure 128 mitigates or prevents diffusion of the first conductive material from the vertical bond structure 128, thereby increasing a stability and reliability of the integrated chip. In some embodiments, the second conductive material of the diffusion barrier layer 126 may, for example, be or comprise tantalum, tantalum nitride, titanium, titanium nitride, some other conductive material, or any combination of the foregoing. In further embodiments, the first conductive material of the vertical bond structure 128 is different from the second conductive material of the diffusion barrier layer 126.

A thickness 216 of the diffusion barrier layer 126 is, for example, about 50 angstroms, within a range of about 10 to 250 angstroms, or some other suitable value. A height 214 of the vertical bond structure 128 is, for example, within a range of about 8,000 to 10,000 angstroms or some other suitable value. In some embodiments, the height 214 of the vertical bond structure 128 being greater than 8,000 angstroms maintains or increases a structural integrity of the bond pad 120. In further embodiments, the height 214 of the vertical bond structure 128 being less than 10,000 angstroms facilitates the lower bond structures 122 providing a good vertical electrical connection between the interconnect structure 106 and the upper pad structure 124 while facilitating a height 215 of the bond pad 120 being relatively low for applications that call for a low profile. Further, the diffusion barrier layer 126 has the thickness 216 along opposing sidewalls of the vertical bond structure 128. In some embodiments, a width of the vertical bond structure 128 is greater than the thickness 216 of the diffusion barrier layer 126. This facilities an overall resistivity of the lower bond structures 122 being relatively low. In some embodiments, the height 215 of the bond pad 120 is within a range of about 8,300 to 14,250 or some other suitable value. In further embodiments, a height 211 of the lower bond structures 122 is greater than a height 213 of the upper pad structure 124. As a result, a good vertical electrical connection between the interconnect structure 106 and the bond pad 120 may be achieved while reducing the height 215 of the bond pad 120.

In some embodiments, the upper pad structure 124 comprises a first conductive layer 130 over the lower bond structures 122 and a second conductive layer 132 overlying the first conductive layer 130. In some embodiments, outer sidewalls of the first conductive layer 130 are aligned with outer sidewalls of the second conductive layer 132. The first conductive layer 130 comprises a third conductive material and the second conductive layer 132 comprises a fourth conductive material. In some embodiments, the third conductive material is different from the fourth conductive material. In various embodiments, the first conductive layer 130 direct contacts and continuously extends over an entirety of top surfaces of the lower bond structures 122. The first conductive layer 130 is configured to mitigate diffusion of the first conductive material (e.g., copper) from the vertical bond structure 128, thereby further increasing the reliability and endurance of the integrated chip. The second conductive layer 132 is configured to mitigate damage to underlying layers and/or structures of the bond pad 120 from an etchant (e.g., vapor hydrogen fluoride) utilized to prepare the bond pad 120 for a bonding process. Further, the protection layer 134 extending along opposing sidewalls of the upper pad structure 124 and comprising the metal oxide (e.g., aluminum oxide) further reduces damage to the bond pad 120 from the etchant. As a result, damage (e.g., delamination and/or stress) to the bond pad 120 is reduced, thereby further increasing the reliability and endurance of the integrated chip. Thus, the bond pad 120 comprising the upper pad structure 124 and the lower bond structures 122 configured as illustrated and/or described above increases an overall performance of the integrated chip.

The third conductive material of the first conductive layer 130 may, for example, be or comprise tantalum, tantalum nitride, titanium, titanium nitride, some other conductive material, or any combination of the foregoing. In various embodiments, the third conductive material of the first conductive layer 130 is the same as the second conductive material of the diffusion barrier layer 126. The fourth conductive material of the second conductive layer 132 may, for example, be or comprise titanium, platinum, or some other suitable conductive material. In various embodiments, the first conductive material is different from the second, third, and fourth conductive materials. In further embodiments, the fourth conductive material is different from the second and third conductive materials. In some embodiments, a resistivity of the vertical bond structure 128 is less than an overall resistivity of the upper pad structure 124. In further embodiments, an overall resistivity of the lower bond structures 122 is less than the overall resistivity of the upper pad structure 124.

A thickness 212 of the first conductive layer 130 is, for example, about 600 angstroms, within a range of about 200 to 1,000 angstroms, or some other suitable value. In some embodiments, the thickness 212 being greater than 200 angstroms facilitates the first conductive layer 130 mitigating diffusion of the first conductive material from the vertical bond structure 128. In further embodiments, the thickness 212 being less than about 1,000 angstroms facilitates the bond pad 120 having a relatively low overall resistivity. A thickness 210 of the second conductive layer 132 is, for example, about 500 angstroms, within a range of about 100 to 1,000 angstroms, or some other suitable value. In various embodiments, the thickness 210 being greater than 100 angstroms facilitates mitigating damage to layers of the bond pad 120 under the second conductive layer 132 from the etchant (e.g., vapor hydrogen fluoride). In yet further embodiments, the thickness 210 being less than 1,000 angstroms facilitates the bond pad 120 having the relatively low overall resistivity. In some embodiments, the thickness 212 of the first conductive layer 130 is greater than the thickness 210 of the second conductive layer 132. In yet further embodiments, the height 214 of the vertical bond structure 128 is greater than a height of the upper pad structure 124.

FIG. 2B illustrates a cross-sectional view of some embodiments of an integrated chip 200b corresponding to some other embodiments of the integrated chip 200a of FIG. 2A, in which the semiconductor device 104 is or comprises a device structure 222 disposed within and/or on the semiconductor substrate 102. In various embodiments, the device structure 222 may be or comprise one or more doped region(s) disposed in the semiconductor substrate 102 (e.g., a doped contact region or a doped region of the semiconductor device 104 such as a doped capacitor region, a doped source/drain region, a doped waveguide region, etc.), a semiconductor material (e.g., germanium, epitaxial silicon, etc.) disposed in the semiconductor substrate 102, or the like.

FIG. 2C illustrates a cross-sectional view of some embodiments of an integrated chip 200c corresponding to some other embodiments of the integrated chip 200a of FIG. 2A, in which the upper pad structure further comprises a third conductive layer 224 disposed between the first and second conductive layers 130, 132. In some embodiments, the third conductive layer 224 may, for example, be or comprise titanium nitride, tantalum, copper, silver, another conductive material, or any combination of the foregoing. A thickness 226 of the third conductive layer 224 may, for example, be about 100 angstroms, within a range of about 100 to 1,000 angstroms, or some other suitable value. In various embodiments, the thickness 210 of the second conductive layer 132 is within a range of about 300 to 1,000 angstroms, or some other suitable value. In some embodiments, the thickness 212 of the first conductive layer 130 is less than the thickness 210 of the second conductive layer 132 and the thickness 212 of the first conductive layer 130 is greater than the thickness 226 of the third conductive layer 224.

FIGS. 2D and 2E illustrates a cross-sectional view and a top view of some embodiments of an integrated chip 200d corresponding to some other embodiments of the integrated chip 200a of FIG. 2A. FIG. 2D illustrates the cross-sectional view of the integrated chip taken along the line A-A′ of the top view of FIG. 2E. In the top view of FIG. 2E the upper pad structure 124 is represented by a dashed box.

As seen in the cross-sectional view of FIG. 2D, the protection layer 134 continuously extends along a top surface of the upper pad structure 124 and the dielectric layer 220 overlies the bond pad 120. Further, a width of the topmost conductive wire 112t is less than a width of the upper pad structure 124. As seen in the top view of FIG. 2E, the diffusion barrier layer 126 continuously laterally wraps around an outer perimeter of the vertical bond structure 128. Further, in some embodiments when viewed in the top view the vertical bond structure 128 is elongated in a first direction (e.g., along the y-axis) such that a length 230 of the vertical bond structure 128 is greater than a width 232 of the vertical bond structure 128.

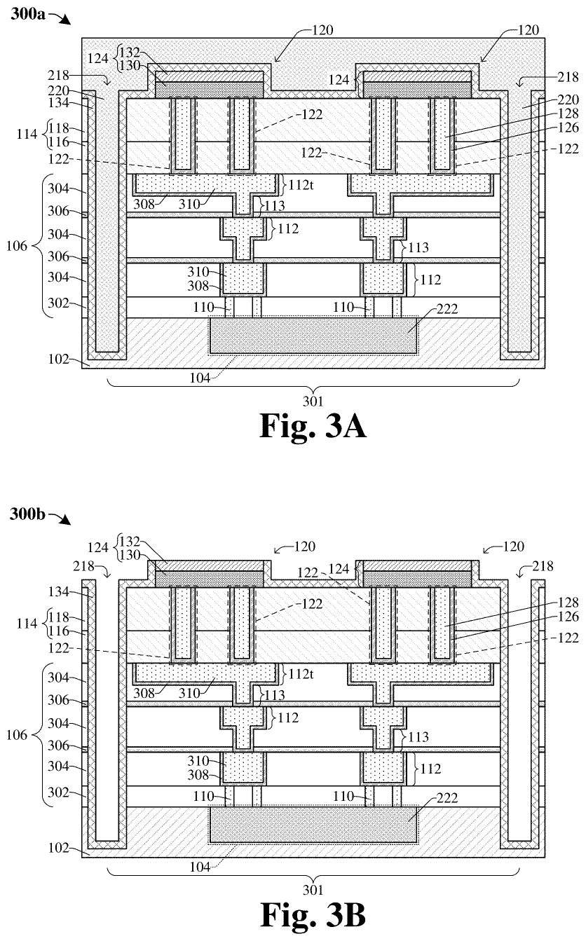

FIG. 3A illustrates a cross-sectional view of some embodiments of an integrated chip 300a comprising a plurality of bond pads 120 disposed over an interconnect structure 106. The bond pads 120 may be configured as illustrated and/or described in FIG. 1, 2A, 2B, 2C, or 2D.

The integrated chip 300a comprises a semiconductor die 301, where the plurality of bond pads 120 and the semiconductor device 104 are part of the semiconductor die 301. Further, the semiconductor die 301 is spaced between isolation trenches 218, where other semiconductor dies (not shown) are disposed on the semiconductor substrate 102 on opposing sides of the semiconductor die 301. In various embodiments, the isolation trenches 218 are disposed along and/or define scribe lines spaced on opposing sides of the semiconductor die 301. The protection layer 134 lines the isolation trenches 218 and the dielectric layer 220 fills the isolation trenches 218 and overlies the bond pads 120.

The interconnect structure 106 is disposed on the semiconductor substrate 102 and electrically couples the semiconductor device 104 to the plurality of bond pads 120. The interconnect structure 106 comprises a plurality of conductive interconnect layers arranged within an interconnect dielectric structure. The interconnect dielectric structure includes an inter-level dielectric (ILD) layer 302, a plurality of inter-metal dielectric (IMD) layers 304, and a plurality of etch stop layers 306. The ILD and IMD layers 302, 304 may, for example, be or comprise silicon dioxide, silicon glass, un-doped silicon glass, a low-k dielectric material, some other dielectric material, or any combination of the foregoing. The etch stop layers 306 may, for example, be or comprise silicon nitride, silicon carbide, another dielectric material, or the like.

The plurality of conductive interconnect layers includes a plurality of conductive contacts 110, a plurality of conductive wires 112, and a plurality of conductive vias 113 vertically stacked with one another. The conductive wires 112 and the conductive vias 113 respectively comprise a conductive body 310 and a lower diffusion barrier layer 308 disposed along sidewalls and lower surface(s) of the conductive body 310. The interconnect structure 106 comprises topmost conductive wires 112t disposed at a top of the interconnect structure 106. The conductive body 310 may, for example, be or comprise copper, aluminum, aluminum copper, tungsten, some other conductive material, or the like. The lower diffusion barrier layer 308 may, for example, be or comprise tantalum, tantalum nitride, titanium, titanium nitride, some other conductive material, or any combination of the foregoing.

In some embodiments, the conductive body 310 and the vertical bond structure 128 both comprise a first material (e.g., copper). In further embodiments, the vertical bond structure 128 comprises the first material (e.g., copper) and the conductive body 310 comprises a second material (e.g., aluminum) different from the first material. In such embodiments, a resistivity of the vertical bond structure 128 is less than a resistivity of the conductive body 310. In various embodiments, the diffusion barrier layer 126 and the lower diffusion barrier layer 308 both comprise a third material (e.g., titanium nitride or tantalum nitride). In yet further embodiments, the diffusion barrier layer 126 comprises the third material (e.g., titanium nitride) and the lower diffusion barrier layer 308 comprises a fourth material (e.g., tantalum nitride) different from the third material.

FIG. 3B illustrates a cross-sectional view of some embodiments of an integrated chip 300b corresponding to some other embodiments of the integrated chip 300a of FIG. 3A, in which the dielectric layer (220 of FIG. 3A) is omitted. In some embodiments, the protection layer 134 is offset from top surfaces of the bond pads 120.

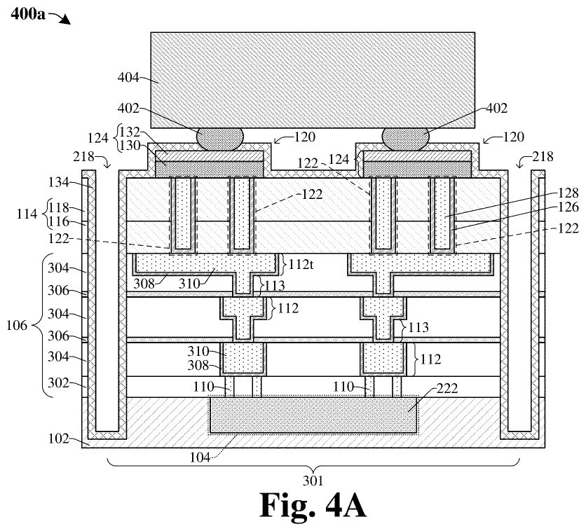

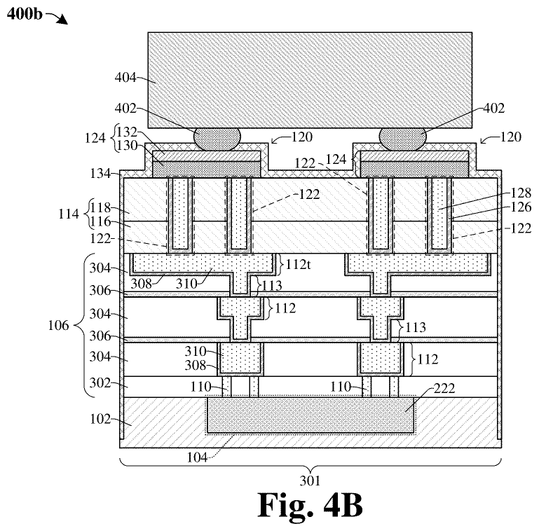

FIG. 4A illustrates a cross-sectional view of some embodiments of a stacked integrated chip structure 400a having an upper semiconductor die 404 bonded to a semiconductor die 301. In some embodiments, the semiconductor die 301 is configured as illustrated and/or described in FIG. 3A or FIG. 3B.

In some embodiments, the upper semiconductor die 404 is configured as a micro-LED die and may comprise a plurality of LEDs disposed on an upper substrate (not shown), a plurality of vertical-cavity surface-emitting lasers (VCSELs) disposed on the upper substrate (not shown), other suitable light emitting devices, or any combination of the foregoing. A plurality of bond bumps 402 are disposed between the upper semiconductor die 404 and the bond pads 120. The bond bumps 402 facilitate bonding the upper semiconductor die 404 to the plurality of bond pads 120. Device(s) (not shown) of the upper semiconductor die 404 is/are electrically coupled to the semiconductor device 104 by way of the bond bumps 402 and the bond pads 120. In various embodiments, the bond bumps 402 directly contact a top surface of a corresponding bond pad 120. The plurality of bond bumps 402 may be solder bumps or solder balls. In some embodiments, the bond bumps 402 may, for example, be or comprise gold, silver, tin, lead, some other suitable material, or any combination of the foregoing. In various embodiments, the protection layer 134 directly contacts sidewalls of the bond bumps 402.

FIG. 4B illustrates a cross-sectional view of some embodiments of a stacked integrated chip structure 400b corresponding to some other embodiments of the stacked integrated chip structure 400a of FIG. 4A. In various embodiments, the semiconductor die 301 is singulated from other semiconductor dies (not shown) disposed in other regions of the semiconductor substrate 102. In some embodiments, at least a portion of the protection layer 134 vertically extends along opposing sidewalls of the passivation structure 114, opposing sidewalls of the interconnect structure 106, and opposing sidewalls of the semiconductor substrate 102 after the singulation process.

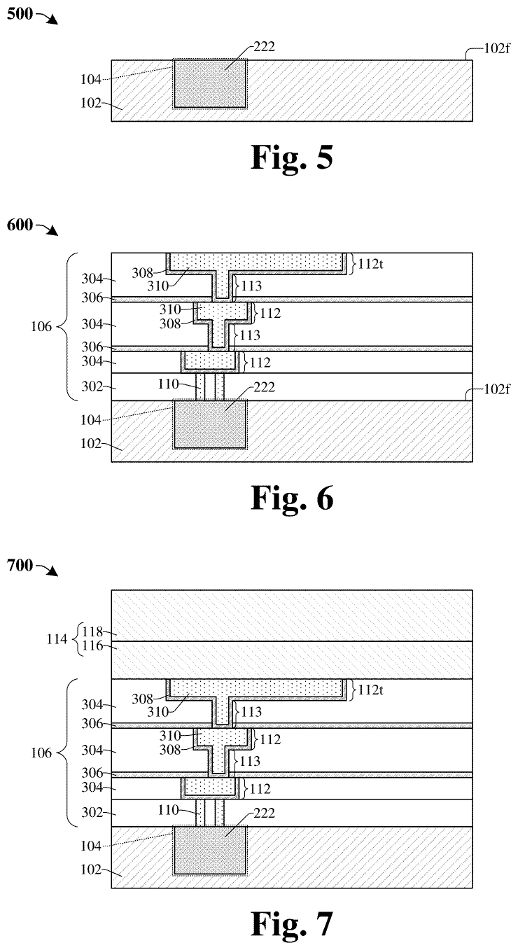

FIGS. 5-16 illustrate cross-sectional views 500-1600 of some embodiments of a method of forming an integrated chip comprising a bond pad having an upper pad structure and a plurality of lower bond structures configured to decrease a contact resistance and increase a reliability of the integrated chip. Although the cross-sectional views 500-1600 shown in FIGS. 5-16 are described with reference to a method, it will be appreciated that the structures shown in FIGS. 5-16 are not limited to the method but rather may stand alone separate of the method. Although FIGS. 5-16 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 500 of FIG. 5, a semiconductor device 104 is formed within and/or on a semiconductor substrate 102. In some embodiments, the semiconductor device 104 may, for example, be or comprise a transistor, a varactor, a resistor, a capacitor, a doped region of the semiconductor substrate 102, or some other suitable semiconductor device. In various embodiments, the semiconductor device 104 comprises a device structure 222 disposed within and/or on the semiconductor substrate 102. In some embodiments, the semiconductor device 104 is formed by one or more deposition process(es), one or more patterning process(es), one or more planarization process(es), one or more doping process(es), some other suitable fabrication process(es), or any combination of the foregoing. In yet further embodiments, the semiconductor device 104 may be configured as a transistor as illustrated and/or described in FIG. 2A.

As shown in cross-sectional view 600 of FIG. 6, an interconnect structure 106 is formed on a front-side surface 102f of the semiconductor substrate 102. The interconnect structure 106 comprises a plurality of conductive interconnect layers arranged within an interconnect dielectric structure. The interconnect dielectric structure includes an inter-level dielectric (ILD) layer 302, a plurality of inter-metal dielectric (IMD) layers 304, and a plurality of etch stop layers 306. The plurality of conductive interconnect layers includes a plurality of conductive contacts 110, a plurality of conductive wires 112, and a plurality of conductive vias 113 vertically stacked with one another. The conductive wires 112 and the conductive vias 113 respectively comprise a conductive body 310 and a lower diffusion barrier layer 308 disposed along sidewalls and lower surface(s) of the conductive body 310. The interconnect structure 106 comprises a topmost conductive wire 112t disposed at a top of the interconnect structure 106.

In some embodiments, the ILD layer 302, the IMD layers 304, and the etch stop layers 306 may each be formed over the semiconductor substrate 102 by a chemical vapor deposition (CVD) process, a physical vapor deposition (PVD) process, an atomic layer deposition (ALD) process, or some other suitable deposition or growth process. In various embodiments, layers of the plurality of conductive contacts 110, the plurality of conductive wires 112, and the plurality of conductive vias 113 may be formed by a single damascene process, a dual damascene process, other suitable fabrication process(es), or the like.

As shown in cross-sectional view 700 of FIG. 7, a passivation structure 114 is formed on the interconnect structure 106. In some embodiments, the passivation structure 114 comprises a first passivation layer 116 vertically stacked with a second passivation layer 118. In various embodiments, the first passivation layer 116 and the second passivation layer 118 may, for example, each be formed by CVD, PVD, ALD, or some other suitable growth or deposition process. The first passivation layer 116 may, for example, be or comprise silicon nitride, silicon carbide, or the like and may be formed to a thickness of about 3,000 angstroms, within a range of about 2,500 to 3,500 angstroms, or some other suitable value. The second passivation layer 118 may, for example, be or comprise silicon dioxide, silicon glass, un-doped silicon glass, or the like and may be formed to a thickness of about 5,500 angstroms, within a range of about 5,000 to 6,000 angstroms, or some other suitable value.

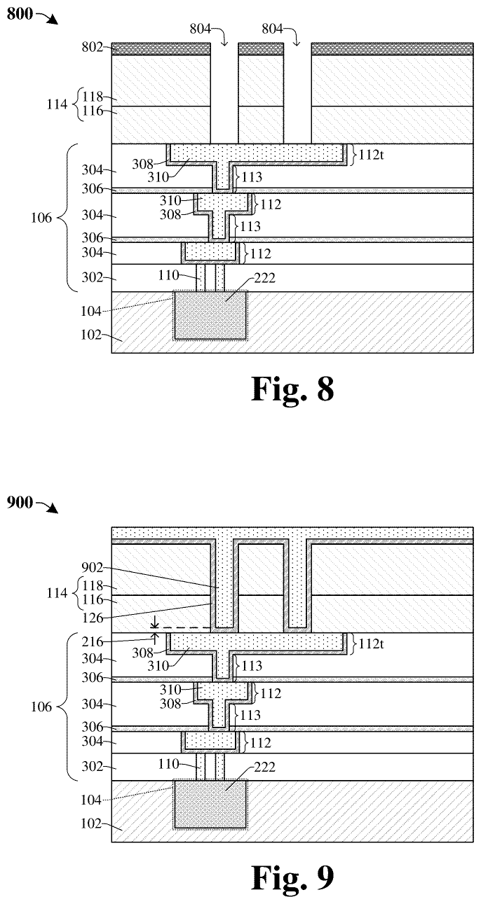

As shown in cross-sectional view 800 of FIG. 8, a patterning process is performed on the passivation structure 114 to form trenches 804 in the passivation structure 114. In some embodiments, the patterning process includes forming a masking layer 802 over the passivation structure 114 and performing an etching process (e.g., a plasma etch process, a reactive-ion etch process, etc.) on the passivation structure 114 according to the masking layer 802. In various embodiments, the masking layer 802 may be removed during the etching process or by a removal process after the etching process (not shown). In further embodiments, the patterning process exposes an upper surface of the topmost conductive wire 112t.

As shown in cross-sectional view 900 of FIG. 9, a diffusion barrier layer 126 is deposited over the passivation structure 114 lining the trenches (804 of FIG. 8) and a conductive structure 902 is deposited on the diffusion barrier layer 126. The diffusion barrier layer 126 is formed, for example, by CVD, PVD, ALD, electroplating, or some other suitable growth or deposition process. The conductive structure 902 is formed, for example, by CVD, PVD, electroplating, or some other suitable growth or deposition process. The diffusion barrier layer 126 may, for example, be or comprise tantalum nitride, tantalum, titanium nitride, titanium, some other conductive material, or any combination of the foregoing. The diffusion barrier layer 126 is formed to a thickness 216 that is, for example, about 50 angstroms, within a range of about 10 to 250 angstroms, or some other suitable value. The conductive structure 902 may, for example, be or comprise copper or the like. In some embodiments, the conductive structure 902 consists of or consists essentially of copper. In various embodiments, the conductive structure 902 and the conductive body 310 comprise a same first conductive material (e.g., copper).

As shown in cross-sectional view 1000 of FIG. 10, a planarization process is performed on the diffusion barrier layer 126 and the conductive structure (902 of FIG. 9), thereby defining vertical bond structures 128 and a plurality of lower bond structures 122 in the passivation structure 114. The plurality of lower bond structures 122 respectively comprise a vertical bond structure 128 and a diffusion barrier layer 126 disposed along opposing sidewalls and a lower surface of the vertical bond structure 128. In some embodiments, the vertical bond structures 128 are formed to a height 214 that may, for example, be within a range of about 8,000 to 10,000 angstroms or some other suitable value. The planarization process may, for example, be or comprise a chemical mechanical planarization (CMP) process or some other suitable planarization process.

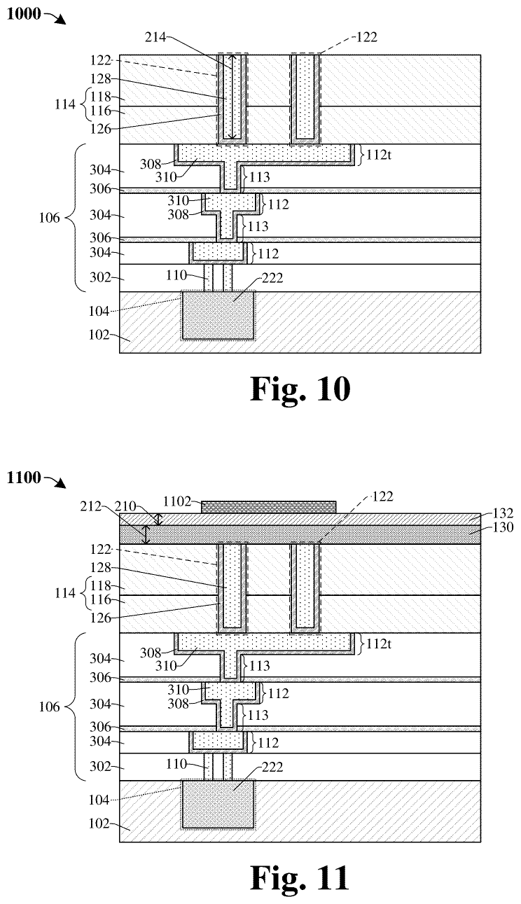

As shown in cross-sectional view 1100 of FIG. 11, a first conductive layer 130 and a second conductive layer 132 are formed over the plurality of lower bond structures 122. Further, a masking layer 1102 is formed over the second conductive layer 132. The first and second conductive layers 130, 132 may each be deposited over the lower bond structures 122 by, for example, CVD, PVD, ALD, electroplating, electroless plating or some other suitable growth or deposition process. In some embodiments, the first conductive layer 130 may, for example, be or comprise tantalum nitride, tantalum, titanium nitride, titanium, some other conductive material, or any combination of the foregoing. In various embodiments, the first conductive layer 130 and the diffusion barrier layer 126 comprise a same second conductive material (e.g., tantalum nitride, tantalum, titanium nitride, titanium, etc.). In further embodiments, the second conductive layer 132 may, for example, be or comprise titanium, platinum, or the like. The first conductive layer 130 is formed to a thickness 212 that may, for example be about 600 angstroms, within a range of about 200 to 1,000 angstroms, or the like. The second conductive layer 132 is formed to a thickness 210 that may, for example, be about 500 angstroms, within a range of about 100 to 1,000 angstroms, or the like.

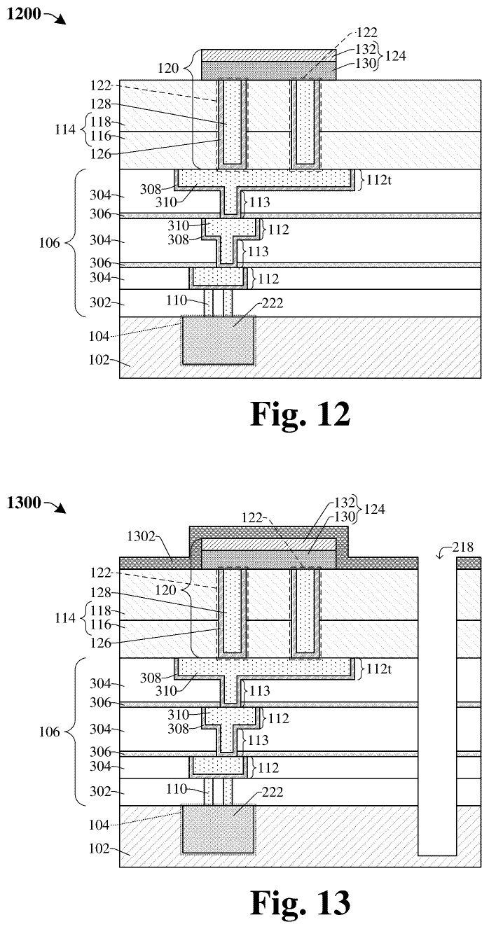

As shown in cross-sectional view 1200 of FIG. 12, a patterning process is performed on the first and second conductive layers 130, 132, thereby defining an upper pad structure 124 and a bond pad 120. In some embodiments, the upper pad structure 124 comprises the first and second conductive layers 130, 132 and the bond pad 120 comprises the upper pad structure 124 and the vertical bond structures 128. In further embodiments, a process for forming the bond pad 120 includes the fabrication steps illustrated and/or described in FIGS. 8-12. In various embodiments, the patterning process includes performing an etching process (e.g., a plasma etch process, a reactive-ion etch process, etc.) on the first and second conductive layers 130, 132 according to the masking layer (1102 of FIG. 11).

As shown in cross-sectional view 1300 of FIG. 13, a patterning process is performed on the passivation structure 114, the interconnect structure 106, and the semiconductor substrate 102 to form one or more isolation trench(es) 218 extending from the passivation structure 114 to the semiconductor substrate 102. In some embodiments, the patterning process includes forming a masking layer 1302 over the passivation structure 114 and performing an etching process (e.g., a plasma etch process, a reactive-ion etch process, etc.) according to the masking layer 1302. In various embodiments, the one or more isolation trench(es) 218 is/are disposed between adjacent semiconductor dies over the semiconductor substrate 102.

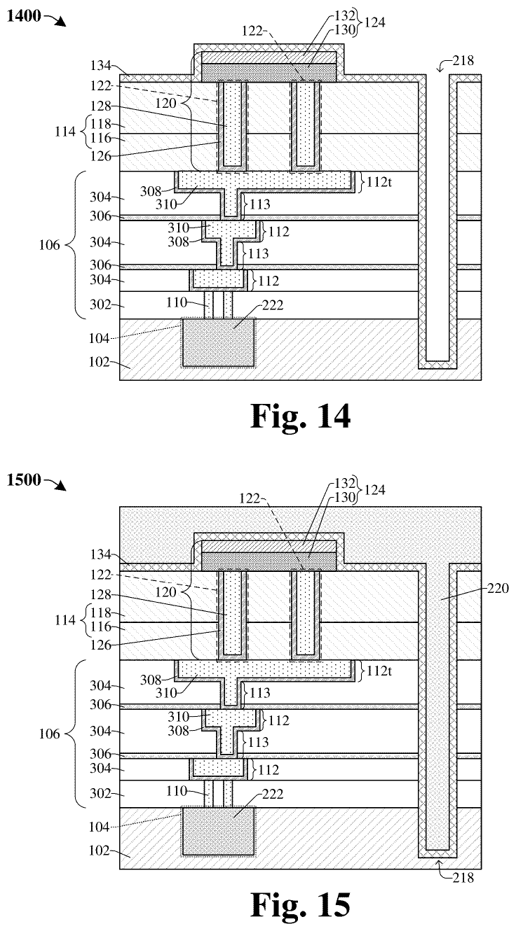

As shown in cross-sectional view 1400 of FIG. 14, a protection layer 134 is deposited over the semiconductor substrate 102. The protection layer 134 may, for example, be formed by CVD, PVD, ALD, or some other suitable growth or deposition process. The protection layer 134 may, for example, be or comprise a metal oxide such as aluminum oxide or some other suitable material and is formed to a thickness of about 400 angstroms, within a range of about 300 to 500 angstroms, or some other suitable value. The protection layer 134 extends along sidewalls of the passivation structure 114, sidewalls of the interconnect structure 106, and sidewalls and a lower surface of the semiconductor substrate 102 defining the one or more isolation trench(es) 218. Further, the protection layer 134 extends along a top surface and opposing sidewalls of the upper pad structure 124.

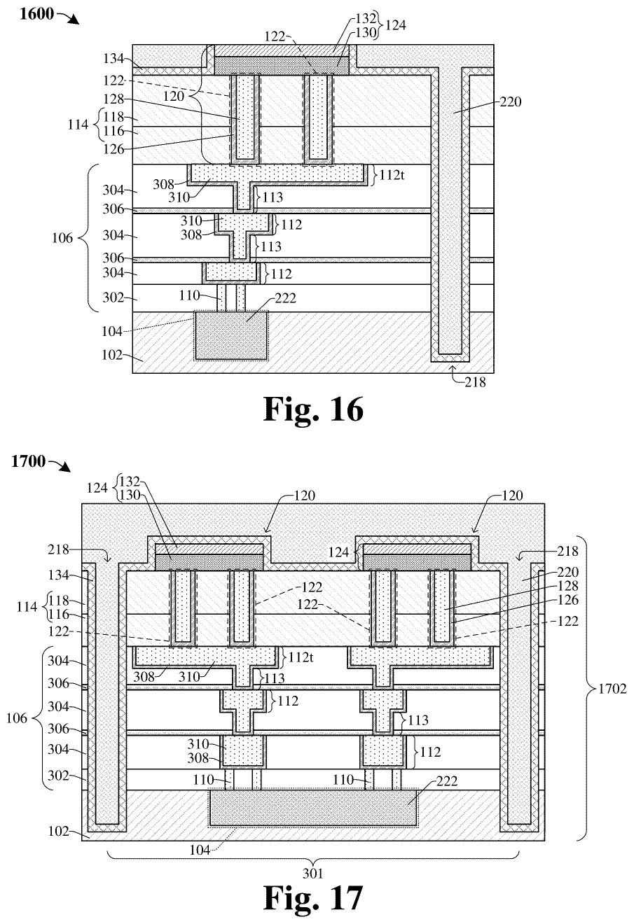

As shown in cross-sectional view 1500 of FIG. 15, a dielectric layer 220 is formed over the semiconductor substrate 102. The dielectric layer 220 may, for example, be formed by CVD, PVD, ALD, or some other suitable growth or deposition process. The dielectric layer 220 overlies the protection layer 134 and fills the one or more isolation trench(es) 218. In some embodiments, the dielectric layer 220 may, for example, be or comprise an oxide such as silicon dioxide or some other dielectric material. In various embodiments, the dielectric layer 220 is configured to provide structural support to layers of the interconnect structure 106, the semiconductor substrate 102, and/or the passivation structure 114. For example, the semiconductor substrate 102 and/or layers of the interconnect structure 106 and the passivation structure 114 may be prone to damage (e.g., warpage, delamination, etc.) at regions around the one or more isolation trench(es) 218. This may occur as the semiconductor substrate 102 is moved between processing chambers and/or while other processing steps are performed on the structure of FIG. 15 (e.g., during the planarization process of FIG. 16). Accordingly, forming the dielectric layer 220 over the semiconductor substrate 102 and within the one or more isolation trench(es) increases a structural integrity of the structure of FIG. 15 and mitigates damage to the semiconductor substrate 102 and/or layers of the interconnect structure 106 and the passivation structure 114. In yet further embodiments, the dielectric layer 220 may provide protection to underlying layers from contaminants during subsequent processing steps and/or while transferring the semiconductor substrate 102 (e.g., transferring the semiconductor substrate 102 between processing chambers).

As shown in cross-sectional view 1600 of FIG. 16, a planarization process is performed on the dielectric layer 220 and the protection layer 134. In some embodiments, the planarization process is a CMP process, an etch process, or some other suitable planarization process and may expose an upper surface of the bond pad 120. In various embodiments, the planarization process of FIG. 16 may be omitted such that the dielectric layer 220 and the protection layer 134 remain over the bond pad 120.

FIGS. 17-20 illustrate cross-sectional views 1700-2000 of some embodiments of a method of forming a stacked integrated chip structure having an upper semiconductor die bonded to bond pads of a semiconductor die. Although the cross-sectional views 1700-2000 shown in FIGS. 17-20 are described with reference to a method, it will be appreciated that the structures shown in FIGS. 17-20 are not limited to the method but rather may stand alone separate of the method. Although FIGS. 17-20 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 1700 of FIG. 17, an integrated chip 1702 comprising a plurality of bond pads 120 is formed. In various embodiments, the integrated chip 1702 may be formed by the fabrication processes illustrated and/or described in FIGS. 5-15. The integrated chip 1702 comprises a semiconductor device 104 formed within and/or on a semiconductor substrate 102. An interconnect structure 106 and a passivation structure 114 are formed over the semiconductor substrate 102. The plurality of bond pads 120 are formed over the interconnect structure 106 and are electrically coupled to the interconnect structure 106. The integrated chip 1702 comprises a semiconductor die 301, where the plurality of bond pads 120 and the semiconductor device 104 are part of the semiconductor die 301. Further, the semiconductor die 301 is spaced between isolation trenches 218, where other semiconductor dies (not shown) are disposed on the semiconductor substrate 102 on opposing sides of the semiconductor die 301. In various embodiments, the isolation trenches 218 are disposed along and/or define scribe lines spaced on opposing sides of the semiconductor die 301. The protection layer 134 lines the isolation trenches 218 and the dielectric layer 220 fills the isolation trenches 218.

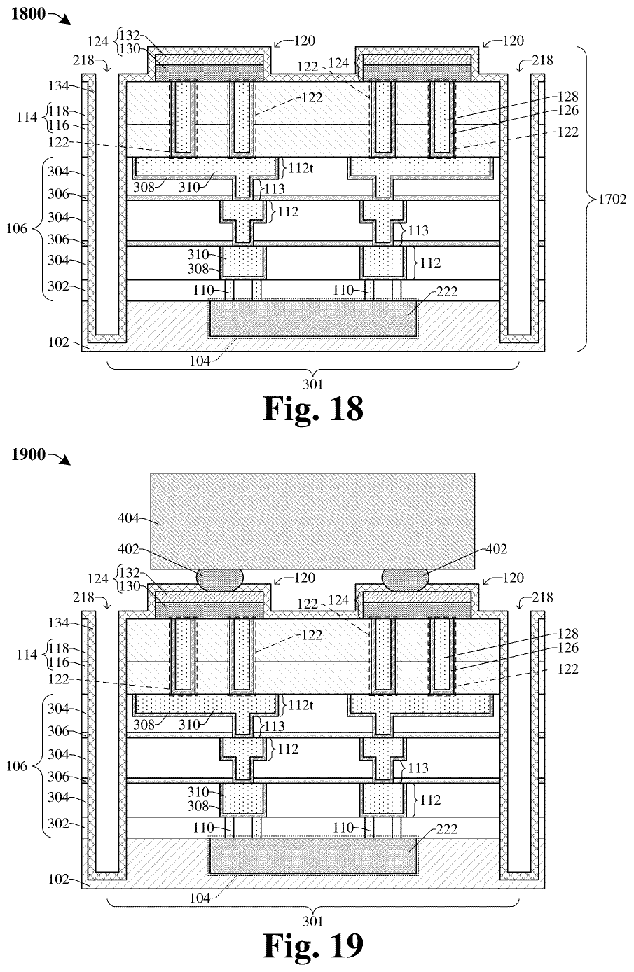

As shown in cross-sectional view 1800 of FIG. 18, an etching process is performed on the integrated chip 1702 to remove the dielectric layer (220 of FIG. 17) from over the semiconductor substrate 102. In various embodiments, the etching process includes exposing the structure of FIG. 17 to an etchant (e.g., vapor hydrogen fluoride) to remove the dielectric layer (220 of FIG. 17). By virtue of the protection layer 134 extending along sidewalls and the top surface of the upper pad structure 124, damage to the bond pads 120 is mitigated. Further, in some embodiments, the top surface of the upper pad structure 124 may be exposed during the etching process. The second conductive layer 132 comprises a conductive material (e.g., titanium or platinum) having a low reactivity to the etchant, thereby mitigating damage to the bond pads 120.

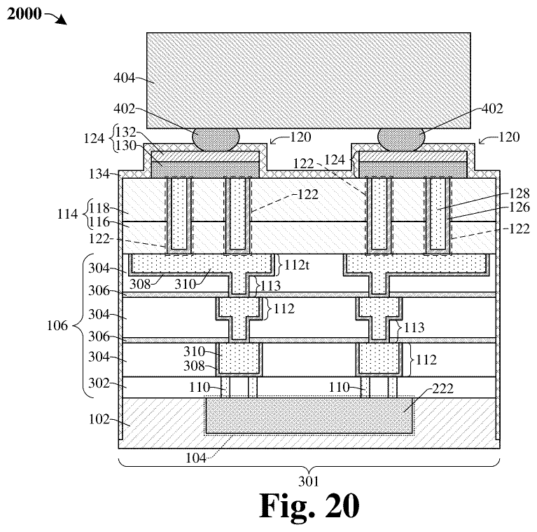

As shown in cross-sectional view 1900 of FIG. 19, an upper semiconductor die 404 is provided and bonded to the plurality of bond pads 120. In some embodiments, bonding the upper semiconductor die 404 to the plurality of bond pads 120 includes: etching (e.g., by a plasma etch, a reactive-ion etch, etc.) the protection layer 134 to expose top surfaces of the bond pads 120; forming a plurality of bond bumps 402 over the bond pads 120; and performing a metallic bonding process to bond the upper semiconductor die 404 to the bond pads 120. In various embodiments, instead of etching the protection layer 134 a planarization process (e.g., a CMP process) may be performed on the protection layer 134 before forming the plurality of bond bumps 402. In some embodiments, the aforementioned planarization process may be performed before the etching process of FIG. 18. In yet further embodiments, the plurality of bond bumps 402 are formed on the upper semiconductor die 404 before bonding the upper semiconductor die 404 to the plurality of bond pads 120.

As shown in cross-sectional view 2000 of FIG. 20, a singulation process is performed along the plurality of isolation trenches (218 of FIG. 19) to singulate the semiconductor die 301. In some embodiments, the singulation process includes cutting the structure of FIG. 19 along the isolation trenches (218 of FIG. 19) with a saw blade (not shown). In various embodiments, the saw blade may be attached to a housing (not shown) that holds a motor (not shown) driving a rotor to which the saw blade is fixed. In yet further embodiments, the singulation process may be performed by a diamond saw blade cutting process, a laser cutting pross, a plasma etching process, some other suitable singulation process, or any combination of the foregoing.

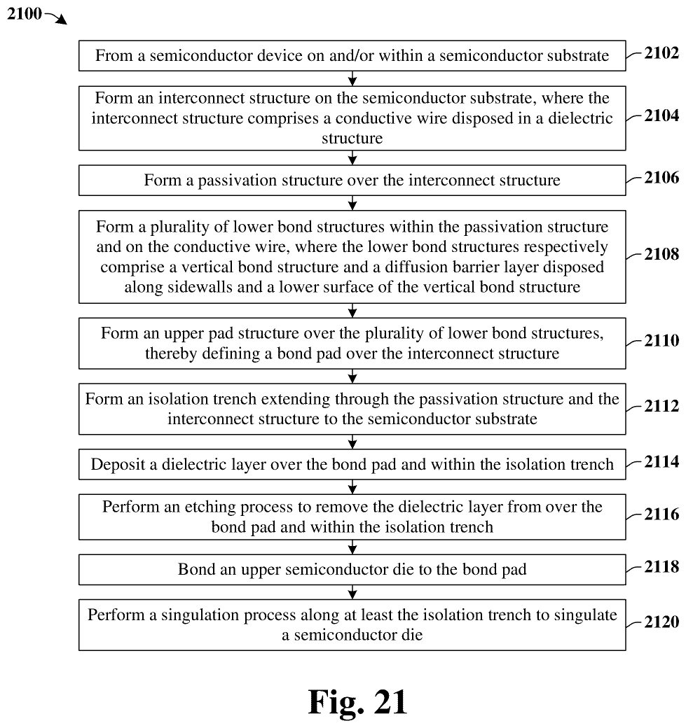

FIG. 21 illustrates a method 2100 for forming a stacked integrated chip structure having an upper semiconductor die bonded to bond pads of a semiconductor die. Although the method 2100 illustrates and/or describes a series of acts or events, it will be appreciated that the method 2100 is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2102, a semiconductor device is formed on and/or within a semiconductor substrate. FIG. 5 illustrates cross-sectional view 500 corresponding to various embodiments of act 2102.

At act 2104, an interconnect structure is formed on the semiconductor substrate, where the interconnect structure comprises a conductive wire disposed in a dielectric structure. FIG. 6 illustrates cross-sectional view 600 corresponding to various embodiments of act 2104.

At act 2106, a passivation structure is formed over the interconnect structure. FIG. 7 illustrates cross-sectional view 700 corresponding to various embodiments of act 2106.

At act 2108, a plurality of lower bond structures are formed within the passivation structure and on the conductive wire. The lower bond structures respectively comprise a vertical bond structure and a diffusion barrier layer disposed along sidewalls and a lower surface of the vertical bond structure. FIGS. 8-10 illustrate cross-sectional views 800-1000 corresponding to various embodiments of act 2108.

At act 2110, an upper pad structure is formed over the plurality of lower bond structures, thereby defining a bond pad over the interconnect structure. FIGS. 11 and 12 illustrate cross-sectional views 1100 and 1200 corresponding to various embodiments of act 2110.

At act 2112, an isolation trench is formed extending through the passivation structure and the interconnect structure to the semiconductor substrate. FIG. 13 illustrates cross-sectional view 1300 corresponding to various embodiments of act 2112.

At act 2114, a dielectric layer is deposited over the bond pad and within the isolation trench. FIG. 15 illustrates cross-sectional view 1500 corresponding to various embodiments of act 2114.

At act 2116, an etching process is performed to remove the dielectric layer from over the bond pad and within the isolation trench. FIG. 18 illustrates cross-sectional view 1800 corresponding to various embodiments of act 2116.

At act 2118, an upper semiconductor die is bonded to the bond pad. FIG. 19 illustrates cross-sectional view 1900 corresponding to various embodiments of act 2118.

At act 2120, a singulation process is performed along the isolation trench to singulate a semiconductor die. FIG. 20 illustrates cross-sectional view 2000 corresponding to various embodiments of act 2120.

Accordingly, in some embodiments, the present disclosure relates to an integrated chip comprising a bond pad having an upper bad structure and a plurality of lower bond structures, where the lower bond structures respectively comprise a vertical bond structure configured to decrease a contact resistance of the bond pad.

In some embodiments, the present application provides an integrated chip, including: an interconnect structure overlying a substrate and comprising a conductive wire disposed in a dielectric structure, wherein the conductive wire comprises a body structure; a passivation structure overlying the interconnect structure; and a bond pad over the passivation structure, wherein the bond pad comprises an upper pad structure on the passivation structure and a plurality of lower bond structures extending through the passivation structure to the conductive wire, wherein the lower bond structures respectively comprise a vertical bond structure and a diffusion barrier layer disposed along a lower surface and opposing sidewalls of the vertical bond structure, wherein the upper pad structure comprises a first conductive layer vertically stacked with a second conductive layer. In an embodiment, the body structure and the vertical bond structure comprise a first material, wherein a conductivity of the first material is greater than that of tungsten. In an embodiment, the body structure and the vertical bond structure comprise copper. In an embodiment, the first conductive layer directly contacts a top surface of the vertical bond structure and a top surface of the diffusion barrier layer, wherein the first and second conductive layers comprise different materials. In an embodiment, the first conductive layer and the diffusion barrier layer comprise a second material different from the first material. In an embodiment, a thickness of the first conductive layer is greater than a thickness of the second conductive layer. In an embodiment, the upper pad structure further comprises a third conductive layer disposed between the first and second conductive layers, wherein a material of the third conductive layer is different from materials of the first and second conductive layers. In an embodiment, the conductive wire further comprises a lower diffusion barrier layer disposed along opposing sidewalls and a lower surface of the body structure, wherein the lower diffusion barrier layer and the diffusion barrier layer comprise a material different from that of the body structure and the vertical bond structure. In an embodiment, the integrated chip further includes: a micro-light emitting diode (LED) die disposed on the bond pad, wherein the micro-LED die is electrically coupled to the interconnect structure by way of the bond pad; and a bond bump disposed between the micro-LED die and the bond pad.

In some embodiments, the present application provides an integrated chip including: a semiconductor device disposed on a semiconductor substrate; an interconnect structure overlying the semiconductor substrate, wherein the interconnect structure comprises a conductive wire electrically coupled to the semiconductor device; a passivation structure overlying the interconnect structure; and a bond pad disposed on the passivation structure and electrically coupled to the conductive wire, wherein the bond pad comprises an upper pad structure and a plurality of lower bond structures disposed in the passivation structure, wherein the upper pad structure comprises a first conductive layer and a second conductive layer over the first conductive layer, wherein the lower bond structures comprise a vertical bond structure and a diffusion barrier layer laterally enclosing the vertical bond structure, wherein the first conductive layer directly contacts top surfaces of the vertical bond structure and the diffusion barrier layer, and wherein the vertical bond structure comprises copper. In an embodiment, the integrated chip further includes: a trench extending through the passivation structure and the interconnect structure to the semiconductor substrate; and a protection layer disposed along sidewalls of the upper pad structure and lining the trench, wherein the protection layer continuously laterally extends from the upper pad structure to the trench. In an embodiment, a height of the upper bad structure is less than a height of the plurality of lower bond structures. In an embodiment, the diffusion barrier layer and the first conductive layer are respectively configured to mitigate diffusion of copper from the vertical bond structure. In an embodiment, the second conductive layer comprises titanium or platinum. In an embodiment, the upper pad structure further comprises a third conductive layer disposed between the first and second conductive layers, wherein a thickness of the first conductive layer is less than a thickness of the second conductive layer, wherein a thickness of the third conductive layer is less than the thickness of the first conductive layer.

In some embodiments, the present application provides a method for forming an integrated chip, the method including: forming an interconnect structure over a semiconductor substrate, wherein the interconnect structure comprises a conductive wire; depositing a passivation structure over the interconnect structure; patterning the passivation structure to form a plurality of openings in the passivation structure over the conductive wire; depositing a diffusion barrier layer over the passivation structure and lining the openings; forming vertical bond structures over the diffusion barrier layer and filling the openings, wherein the diffusion barrier layer laterally wraps around the vertical bond structures, wherein the vertical bond structures and the conductive wire comprise a first material; and forming an upper pad structure over the vertical bond structures, wherein the upper pad structure comprises a first conductive layer on the vertical bond structures and a second conductive layer over the first conductive layer, wherein outer sidewalls of the first conductive layer are aligned with outer sidewalls of the second conductive layer. In an embodiment, a resistivity of the vertical bond structures is less than an overall resistivity of the upper pad structure. In an embodiment, the method further includes: performing a patterning process to form a trench extending through the passivation structure and the interconnect structure to the semiconductor substrate; depositing a protection layer over the passivation structure, wherein the protection layer lines the trench and is disposed along opposing sidewalls of the upper pad structure; and depositing a dielectric layer over the upper pad structure and within the trench. In an embodiment, the method further includes: performing an etching process to remove the dielectric layer from over the passivation structure and within the trench; and bonding an upper semiconductor die to the upper pad structure. In an embodiment, the method further includes performing a singulation process along the trench to singulate a semiconductor die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
an interconnect structure overlying a substrate and comprising a conductive wire disposed in a dielectric structure, wherein the conductive wire comprises a body structure;
a passivation structure overlying the interconnect structure; and
a bond pad over the passivation structure, wherein the bond pad comprises an upper pad structure on the passivation structure and a plurality of lower bond structures extending through the passivation structure to the conductive wire, wherein the lower bond structures respectively comprise a vertical bond structure and a diffusion barrier layer disposed along a lower surface and opposing sidewalls of the vertical bond structure, wherein the upper pad structure comprises a first conductive layer vertically stacked with a second conductive layer.

2. The integrated chip of claim 1, wherein the body structure and the vertical bond structure comprise a first material, wherein a conductivity of the first material is greater than that of tungsten.

3. The integrated chip of claim 1, wherein the body structure and the vertical bond structure comprise copper.

4. The integrated chip of claim 1, wherein the first conductive layer directly contacts a top surface of the vertical bond structure and a top surface of the diffusion barrier layer, wherein the first and second conductive layers comprise different materials.

5. The integrated chip of claim 4, wherein the body structure and the vertical bond structure comprise a first material, wherein the first conductive layer and the diffusion barrier layer comprise a second material different from the first material.

6. The integrated chip of claim 4, wherein a thickness of the first conductive layer is greater than a thickness of the second conductive layer.

7. The integrated chip of claim 4, wherein the upper pad structure further comprises a third conductive layer disposed between the first and second conductive layers, wherein a material of the third conductive layer is different from materials of the first and second conductive layers.

8. The integrated chip of claim 1, wherein the conductive wire further comprises a lower diffusion barrier layer disposed along opposing sidewalls and a lower surface of the body structure, wherein the lower diffusion barrier layer and the diffusion barrier layer comprise a material different from that of the body structure and the vertical bond structure.

9. The integrated chip of claim 1, further comprising:
a micro-light emitting diode (LED) die disposed on the bond pad, wherein the micro-LED die is electrically coupled to the interconnect structure by way of the bond pad; and
a bond bump disposed between the micro-LED die and the bond pad.

10. An integrated chip, comprising:
a semiconductor device disposed on a semiconductor substrate;
an interconnect structure overlying the semiconductor substrate, wherein the interconnect structure comprises a conductive wire electrically coupled to the semiconductor device;
a passivation structure overlying the interconnect structure; and
a bond pad disposed on the passivation structure and electrically coupled to the conductive wire, wherein the bond pad comprises an upper pad structure and a plurality of lower bond structures disposed in the passivation structure, wherein the upper pad structure comprises a first conductive layer and a second conductive layer over the first conductive layer, wherein the lower bond structures comprise a vertical bond structure and a diffusion barrier layer laterally enclosing the vertical bond structure, wherein the first conductive layer directly contacts top surfaces of the vertical bond structure and the diffusion barrier layer, and wherein the vertical bond structure comprises copper.

11. The integrated chip of claim 10, further comprising:
a trench extending through the passivation structure and the interconnect structure to the semiconductor substrate; and
a protection layer disposed along sidewalls of the upper pad structure and lining the trench, wherein the protection layer continuously laterally extends from the upper pad structure to the trench.

12. The integrated chip of claim 10, wherein a height of the upper pad structure is less than a height of the plurality of lower bond structures.

13. The integrated chip of claim 10, wherein the diffusion barrier layer and the first conductive layer are respectively configured to mitigate diffusion of copper from the vertical bond structure.

14. The integrated chip of claim 10, wherein the second conductive layer comprises titanium or platinum.

15. The integrated chip of claim 10, wherein the upper pad structure further comprises a third conductive layer disposed between the first and second conductive layers, wherein a thickness of the first conductive layer is less than a thickness of the second conductive layer, wherein a thickness of the third conductive layer is less than the thickness of the first conductive layer.

16. A method for forming an integrated chip, comprising:
forming an interconnect structure over a semiconductor substrate, wherein the interconnect structure comprises a conductive wire;
depositing a passivation structure over the interconnect structure;
patterning the passivation structure to form a plurality of openings in the passivation structure over the conductive wire;
depositing a diffusion barrier layer over the passivation structure and lining the openings;
forming vertical bond structures over the diffusion barrier layer and filling the openings, wherein the diffusion barrier layer laterally wraps around the vertical bond structures, wherein the vertical bond structures and the conductive wire comprise a first material; and
forming an upper pad structure over the vertical bond structures, wherein the upper pad structure comprises a first conductive layer on the vertical bond structures and a second conductive layer over the first conductive layer, wherein outer sidewalls of the first conductive layer are aligned with outer sidewalls of the second conductive layer.

17. The method of claim 16, wherein a resistivity of the vertical bond structures is less than an overall resistivity of the upper pad structure.

18. The method of claim 16, further comprising:
performing a patterning process to form a trench extending through the passivation structure and the interconnect structure to the semiconductor substrate;
depositing a protection layer over the passivation structure, wherein the protection layer lines the trench and is disposed along opposing sidewalls of the upper pad structure; and
depositing a dielectric layer over the upper pad structure and within the trench.

19. The method of claim 18, further comprising:
performing an etching process to remove the dielectric layer from over the passivation structure and within the trench; and
bonding an upper semiconductor die to the upper pad structure.

20. The method of claim 19, further comprising:
performing a singulation process along the trench to singulate a semiconductor die.
